(19) United States
(12) Patent Application Publication
(10) Pub. No.: US 2026/0123247 A1
(43) Pub. Date: Apr. 30, 2026

(54) DISPLAY APPARATUS, METHOD OF MANUFACTURING THE DISPLAY APPARATUS, AND ELECTRONIC APPARATUS

(71) Applicant: Samsung Display Co., Ltd., Yongin-si (KR)

(72) Inventor: HO LIM, Yongin-si (KR)

(73) Assignee: Samsung Display Co., Ltd., Yongin-si (KR)

(21) Appl. No.: 19/249,074

(22) Filed: Jun. 25, 2025

(30) Foreign Application Priority Data
Oct. 29, 2024 (KR) 10-2024-0150043

(51) Int. Cl. H10K 59/80; H10K 59/12; H10K 59/35; H10K 59/38

(52) U.S. Cl. CPC H10K 59/877; H10K 59/1201; H10K 59/353; H10K 59/38

(57) ABSTRACT

A display apparatus includes a thin-film transistor on a substrate, a light-emitting element electrically connected to the thin-film transistor, a thin-film encapsulation layer on the light-emitting element, a scattering layer on the thin-film encapsulation layer, and a color filter layer on the scattering layer. The scattering layer has irregular wrinkles.

### CROSS-REFERENCE TO RELATED APPLICATION(S)

This application claims priority to and benefits of Korean Patent Application No. 10-2024-0150043 under 35 U.S.C. § 119, filed Oct. 29, 2024, in the Korean Intellectual Property Office (KIPO), the entire contents of which are incorporated herein by reference.

### BACKGROUND

### 1. Technical Field

Embodiments relate to a display apparatus, a method of manufacturing the display apparatus, and an electronic apparatus.

### 2. Description of the Related Art

With the development of various electronic appliances such as mobile phones, personal digital assistants (PDAs), computers, and large-screen televisions (TVs), various types of display apparatuses applicable to electronic appliances have been developed. For example, widely used display apparatuses in the market include liquid-crystal display apparatuses equipped with a backlight unit and organic light-emitting display apparatuses that emit light of different colors from respective pixel areas.

### SUMMARY

Embodiments of the disclosure may provide a display apparatus in which a scattering layer is arranged below a color filter layer to improve display quality, a method of manufacturing the display apparatus, and an electronic apparatus.

However, this objective is merely illustrative, and the scope of the disclosure is not limited thereto.

According to an embodiment of the disclosure, a display apparatus may include a thin-film transistor on a substrate, a light-emitting element electrically connected to the thin-film transistor, a thin-film encapsulation layer on the light-emitting element, a scattering layer on the thin-film encapsulation layer, and a color filter layer on the scattering layer. The scattering layer may have irregular wrinkles.

In an embodiment, the wrinkles may be arranged on the scattering layer in a direction perpendicular to a light of the display apparatus is emitted.

In an embodiment, a thickness of the scattering layer may be in a range of about 0.5 μm to about 10 μm.

In an embodiment, a refractive index of the scattering layer may be in a range of about 1.45 to about 1.75.

In an embodiment, a step difference between valleys and ridges of the scattering layer may be in a range of about 0.1 μm to about 8 μm.

In an embodiment, the scattering layer may include a photocrosslinking reaction material.

In an embodiment, the light-emitting element may include a pixel electrode, a common electrode located on the pixel electrode, and an emission layer arranged between the pixel electrode and the common electrode, the display apparatus may further include a pixel-defining film that covers an edge of the pixel electrode and includes a first opening that defines a light-emitting area of the light-emitting element, and the color filter layer may be arranged to correspond to the first opening.

In an embodiment, the display apparatus may further include a black matrix located on the pixel-defining film and including a second opening corresponding to the first opening.

In an embodiment, the black matrix may include at least one of a metal, an opaque organic film material, carbon black, carbon nanotubes, and a black dye.

In an embodiment, the light-emitting element may include a first light-emitting element, a second light-emitting element, and a third light-emitting element, which are spaced apart from each other, the first light-emitting element may emit red light, the second light-emitting element may emit green light, and the third light-emitting element may emit blue light.

In an embodiment, the color filter layer may include a first color filter arranged above the first light-emitting element, a second color filter arranged above the second light-emitting element, and a third color filter arranged above the third light-emitting element.

In an embodiment, the display apparatus may further include a third opening defined by removing an area of the scattering layer under the third color filter.

In an embodiment, the display apparatus may further include a planarization layer arranged between the scattering layer and the color filter layer.

In an embodiment, a refractive index of the planarization layer may be in a range of about 1.20 to about 1.44.

According to an embodiment of the disclosure, a method of manufacturing a display apparatus may include producing a display layer, forming a scattering layer on the display layer, and forming a color filter layer on the scattering layer. The forming of the scattering layer may include applying, on the display layer, a scattering layer forming material including a photocrosslinking reaction material, and curing the scattering layer forming material applied on the display layer. The scattering layer may have irregular wrinkles formed on a surface of the scattering layer by the curing of the scattering layer forming material.

In an embodiment, the irregular wrinkles may be formed on an upper surface of the scattering layer.

In an embodiment, the producing of the display layer may include forming a substrate, a light-emitting element on the substrate, and a thin-film encapsulation layer on the light-emitting element.

In an embodiment, the light-emitting element may include a pixel electrode, a common electrode located on the pixel electrode, and an emission layer arranged between the pixel electrode and the common electrode. The display method may further include forming a pixel-defining film covering an edge of the pixel electrode and including a first opening that defines a light-emitting area of the light-emitting element. The color filter layer may be arranged to correspond to the first opening.

In an embodiment, the light-emitting element may include a first light-emitting element that emits red light, a second light-emitting element that emits green light, and a third light-emitting element that emits blue light, which are spaced apart from each other. The color filter layer may include a first color filter arranged above the first light-emitting element, a second color filter arranged above the second light-emitting element, and a third color filter arranged above the third light-emitting element. The method may further include, before the forming of the color filter layer, forming a third opening by removing an area of the scattering layer under the third color filter.

In an embodiment, the method may further include, between the forming of the scattering layer and the forming of the color filter layer, forming a planarization layer on the scattering layer.

According to an embodiment of the disclosure, an electronic apparatus may include an input module, a memory storing at least one program, a processor that operates by executing the at least one program, a display apparatus, and a power module that supplies power to the display apparatus. The processor may control the input module to obtain data, and control the display apparatus to visually display the data. The display apparatus may include a thin-film transistor on a substrate, a light-emitting element electrically connected to the thin-film transistor, a thin-film encapsulation layer on the light-emitting element, a scattering layer on the thin-film encapsulation layer, and a color filter layer on the scattering layer. The scattering layer may have irregular wrinkles.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view schematically illustrating a part of a display apparatus according to an embodiment of the disclosure;

FIG. 2 is a schematic cross-sectional view schematically illustrating an embodiment of portion I of the display apparatus illustrated in FIG. 1;

FIG. 3 is a plan view schematically illustrating a portion of a scattering layer, according to an embodiment of the disclosure;

FIGS. 4 to 6 are schematic cross-sectional views illustrating a process of manufacturing a scattering layer, according to an embodiment of the disclosure;

FIG. 7 is a schematic cross-sectional view schematically illustrating another embodiment of portion I of the display apparatus illustrated in FIG. 1;

FIG. 8 is an enlarged view of area A illustrated in FIG. 7;

FIG. 9 is a schematic cross-sectional view schematically illustrating another embodiment of portion I of the display apparatus illustrated in FIG. 1; and

FIG. 10 is a schematic block diagram of an electronic apparatus according to embodiments of the disclosure.

### DETAILED DESCRIPTION OF THE EMBODIMENTS

As the disclosure allows for various changes and numerous embodiments, particular embodiments will be illustrated in the drawings and described in detail. Advantages and features of the disclosure and a method of achieving the same should become clear with embodiments described below in detail with reference to the drawings. However, the disclosure is not limited to the embodiments disclosed below, but may be implemented in various forms.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The term “about” may include variations of, for example, ±20%, ±10%, or ±5%, from the specified numerical value unless otherwise expressly stated. In some contexts, the term may account for rounding, inherent measurement limitations, or standard tolerances recognized in the relevant technical field. When applied to dimensions, concentrations, or other quantifiable parameters, “about” may include minor deviations that would be understood by a person of ordinary skill in the art as insubstantial in the given context. The scope of “about” should be interpreted in view of standard experimental or clinical tolerances applicable to the field of use. A person skilled in the art would recognize that “about” allows for practical deviations that do not materially alter the intended properties of the invention. Similarly, for mechanical dimensions, “about” may include deviations that are within industry-accepted tolerances and do not materially impact the performance of the disclosure.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

For convenience of description, the magnitude of components in the drawings may be exaggerated or reduced. For example, because the size and/or thickness of each component illustrated in the drawing are arbitrarily shown for convenience of description, the disclosure is not necessarily limited to those illustrated in the drawing.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described below in detail with reference to the accompanying drawings, and in describing the embodiments with reference to the drawings, the same or corresponding components are given the same reference numerals, and redundant descriptions thereof will be omitted.

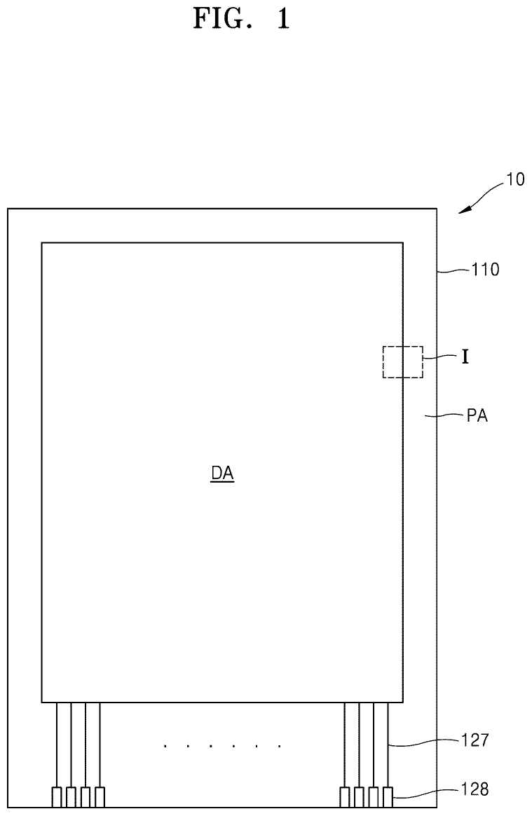

FIG. 1 is a plan view schematically illustrating a part of a display apparatus according to an embodiment of the disclosure.

Referring to FIG. 1, a display apparatus 10 may include, on a substrate 110, a display area DA in which an image is displayed, and a peripheral area PA, which is a non-display area located outside the display area DA and where no image is displayed.

The display area DA may have a quadrangular shape in a plan view. The peripheral area PA may surround the display area DA. However, the disclosure is not limited thereto, and the shape of the display area DA and the shape of the peripheral area PA may be designed relative to each other.

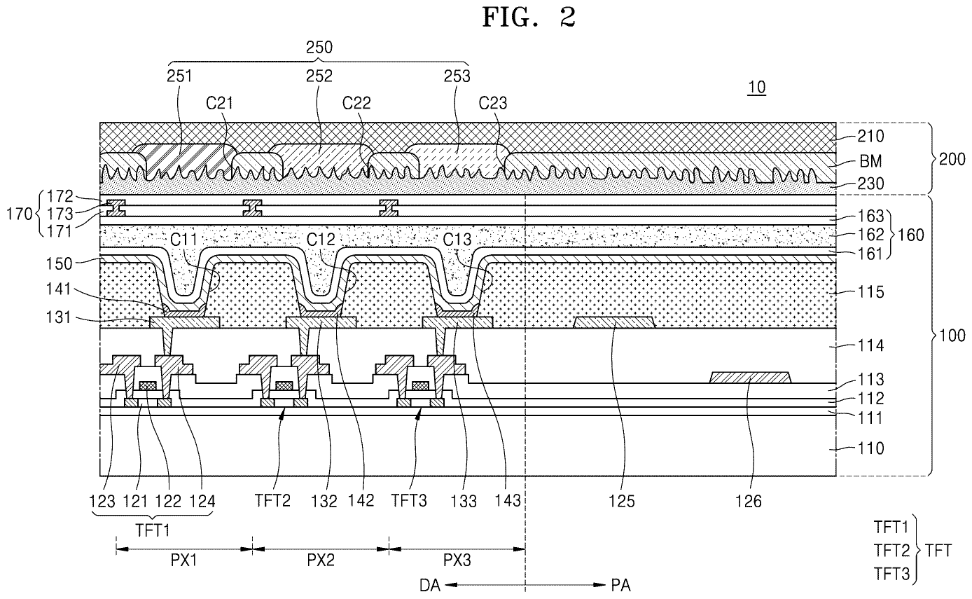

The display area DA may include multiple pixels PX1, PX2, and PX3 (see FIG. 2), and a wiring unit 127 including signal lines, such as scan lines and data lines electrically connected to the pixels PX1, PX2, and PX3 (see FIG. 2), and power lines, such as driving voltage lines, may be electrically connected to a pad electrode 128.

In FIG. 1, the display apparatus 10 is illustrated as having a flat display surface, but the disclosure is not limited thereto. The display apparatus 10 may include a curved display surface or a three-dimensional display surface. The three-dimensional display surface may include multiple display areas facing different directions, and may include, for example, a display surface having a shape of a polygonal prism.

The display apparatus 10 according to an embodiment may be a rigid display apparatus. However, the disclosure is not limited thereto, and in another embodiment, the display apparatus 10 may be a flexible display apparatus. In an embodiment, the display apparatus 10 may be applied to a portable terminal. Although not illustrated, electronic modules, camera modules, power modules, etc. mounted on a main board may be accommodated in a housing to constitute a portable terminal. The display apparatus 10 may be applied to large-sized electronic apparatuses such as televisions or monitors, as well as small and medium-sized electronic apparatuses such as tablets, automotive navigation systems, game consoles, or smart watches.

FIG. 2 is a schematic cross-sectional view schematically illustrating an embodiment of portion I of the display apparatus illustrated in FIG. 1.

Referring to FIG. 2, the display apparatus 10 may include a display layer 100 and a color conversion layer 200 on the display layer 100. The display layer 100 may include the substrate 110, thin-film transistors TFT on the substrate 110, light-emitting elements arranged on and electrically connected to the thin-film transistors TFT, a thin-film encapsulation layer 160 on the light-emitting elements, and a touch sensing layer 170 on the thin-film encapsulation layer 160.

The color conversion layer 200 may include a scattering layer 230 on the touch sensing layer 170, a color filter layer 250 on the scattering layer 230, and a second substrate 210 on the color filter layer 250.

Although not illustrated, the display apparatus 10 may further include other components arranged on the color conversion layer 200. For example, a window substrate, a cover member, etc. may be further arranged on the color conversion layer 200.

The substrate 110 may include a material such as glass, a metal, or a plastic. For example, the substrate 110 may be a flexible substrate including a polymer resin including polyethersulphone, polyacrylate, polyetherimide, polyethylene naphthalate, polyethylene terephthalate, polyphenylene sulfide, polyarylate, polyimide, polycarbonate, or cellulose acetate propionate.

Multiple thin-film transistors TFT1, TFT2, and TFT3 may be arranged on the substrate 110. The display area DA may be an area an image is displayed, and the thin-film transistors TFT1, TFT2, and TFT3 and the pixels PX1, PX2, and PX3 electrically connected to the thin-film transistors TFT1, TFT2, and TFT3, respectively, may be arranged in the display area DA. Although not illustrated in detail in FIG. 2, each pixel may include at least two thin-film transistors and at least one capacitor.

A buffer layer 111 including an inorganic material such as silicon oxide, silicon nitride, and/or silicon oxynitride may be arranged between the thin-film transistor TFT and the substrate 110. The buffer layer 111 may serve to increase a flatness of the upper surface of the substrate 110 or to prevent or reduce the penetration of impurities into a semiconductor layer 121 through the substrate 110.

The first thin-film transistor TFT1 may include a semiconductor layer 121, a gate electrode 122, a source electrode 123, and a drain electrode 124.

The semiconductor layer 121 may include amorphous silicon, polycrystalline silicon, or an organic semiconductor material.

The gate electrode 122 may be arranged above the semiconductor layer 121. The source electrode 123 and the drain electrode 124 may be electrically connected to each other according to a signal applied to the gate electrode 122. The gate electrode 122 may be formed in a single-layer or multi-layer structure including at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), considering adhesion to adjacent layers, surface flatness of a layer to be stacked thereon, processability, and the like.

In order to secure insulation between the semiconductor layer 121 and the gate electrode 122, a gate insulating film 112 including an inorganic material such as silicon oxide, silicon nitride, and/or silicon oxynitride may be arranged between the semiconductor layer 121 and the gate electrode 122.

An interlayer insulating film 113 including an inorganic material such as silicon oxide, silicon nitride, and/or silicon oxynitride may be arranged on the gate electrode 122.

The source electrode 123 and the drain electrode 124 may be arranged on the interlayer insulating film 113. The source electrode 123 and the drain electrode 124 may be electrically connected to the semiconductor layer 121 through contact holes formed in the interlayer insulating film 113 and the gate insulating film 112.

The source electrode 123 and the drain electrode 124 may each be formed in a single-layer or multi-layer structure including at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The second thin-film transistor TFT2 arranged in the second pixel PX2 and the third thin-film transistor TFT3 arranged in the third pixel PX3 and the first thin-film transistor TFT1 described above may include a same material and have a same structure. In another embodiment, the second thin-film transistor TFT2 and the third thin-film transistor TFT3 and the first thin-film transistor TFT1 described above may include different materials and have different structures. The disclosure is not limited to the structure of the thin-film transistors TFT1, TFT2, and TFT3 illustrated in FIG. 2.

Various structures and wires may be arranged in the peripheral area PA of the substrate 110. FIG. 2 schematically illustrates a first power supply line 125 that applies low-voltage power to the light-emitting element, and a second power supply line 126 that applies high-voltage power to the light-emitting element according to an embodiment.

A passivation layer 114 that acts as a planarization film may be arranged on the thin-film transistors TFT1, TFT2, and TFT3. The passivation layer 114 may include an organic insulating material or an inorganic insulating material, or may include a composite of an organic insulating material and an inorganic insulating material. For example, the passivation layer 114 may include an organic material such as an acrylic material, benzocyclobutene (BCB), polyimide, or hexamethyldisiloxane (HMDSO).

In the display area DA, light-emitting elements electrically connected to the thin-film transistors TFT may be arranged on the passivation layer 114.

The light-emitting elements may include pixel electrodes 131, 132, and 133, a common electrode 150 located on the pixel electrodes 131, 132, and 133, and emission layers 141, 142, and 143 arranged between the common electrode 150 and the pixel electrodes 131, 132, and 133.

The first pixel electrode 131, the second pixel electrode 132, and the third pixel electrode 133 may be arranged on the passivation layer 114. The pixel electrodes 131, 132, and 133 may be connected to the drain electrodes 124 of the thin-film transistors TFT1, TFT2, and TFT3 through via holes (not shown) formed in the passivation layer 114, respectively.

The pixel electrodes 131, 132, and 133 may be conductive. The pixel electrodes 131, 132, and 133 may each include a metal alloy or a conductive compound. The pixel electrodes 131, 132, and 133 may each be an anode.

Each of the pixel electrodes 131, 132, and 133 may be a transmissive electrode, a semi-transmissive electrode, or a reflective electrode. In case that the pixel electrodes 131, 132, and 133 are transmissive electrodes, the pixel electrodes 131, 132, and 133 may each include a transparent metal oxide, for example, indium tin oxide (ITO), indium zinc oxide (IZO), zinc oxide (ZnO), or indium tin zinc oxide (ITZO).

In case that the pixel electrode 131, 132, and 133 are semi-transmissive electrodes or reflective electrodes, the pixel electrodes 131, 132, and 133 may each include Ag, Mg, Cu, Al, Pt, Pd, Au, Ni, Nd, Ir, Cr, Li, Ca, LiF/Ca, LiF/Al, Mo, Ti, or a compound or a mixture thereof (e.g., a mixture of Ag and Mg). In another embodiment, the pixel electrodes 131, 132, and 133 may each have a multi-layer structure including a reflective film or a semi-transparent film formed of the above material, and a transparent conductive film formed of indium tin oxide (ITO), Indium zinc oxide (IZO), zinc oxide (ZnO), indium tin zinc oxide (ITZO), or the like. For example, the pixel electrodes 131, 132, and 133 may each have a three-layer structure of ITO/Ag/ITO, but the disclosure is not limited thereto.

The emission layer 141, 142, and 143 may each include a layer made of a material, a layer made of different materials, or layers made of different materials.

Intermediate layers (not shown) including the emission layers 141, 142, and 143 may be formed on the pixel electrodes 131, 132, and 133, respectively.

The intermediate layer may include a low-molecular-weight or high-molecular-weight material. In case that the intermediate layer includes a low-molecular-weight material, the intermediate layer may have a single or composite structure in which a hole injection layer, a hole transport layer, an electron transport layer, and an electron injection layer are stacked. The intermediate layer may include an organic material, such as copper phthalocyanine, N,N-di(naphthalene-1-yl)-N,N′-diphenyl-benzidine (NPB), tris-8-hydroxyquinoline aluminum (Alq3), etc. The intermediate layer may be formed by a method, such as vacuum deposition.

In case that the intermediate layer includes a high-molecular-weight material, the intermediate layer may include a hole transport layer. The hole transport layer may include poly(3,4-ethylenedioxythiophene) (PEDOT), and the emission layer may include a high-molecular-weight material such as a polyphenylene vinylene (PPV)-based material or a polyfluorene-based material. The intermediate layers may be formed by using a method, such as screen printing, inkjet printing, or laser-induced thermal imaging (LITI).

The intermediate layers may be formed integrally across the pixel electrodes 131, 132, and 133, or may be patterned to correspond to the pixel electrodes 131, 132, and 133, respectively.

The common electrode 150 may be formed integrally in all pixels, on the emission layers 141, 142, and 143 of the respective pixels PX1, PX2, and PX3.

The common electrode 150 may be a transmissive electrode, a semi-transmissive electrode, or a reflective electrode. In case that the common electrode 150 is a transmissive electrode, the common electrode 150 may include a transparent metal oxide, for example, indium tin oxide (ITO), indium zinc oxide (IZO), zinc oxide (ZnO), or indium tin zinc oxide (ITZO).

The common electrode 150 may be formed as a transmissive electrode. In case that the common electrode 150 is formed as a transmissive electrode, the common electrode 150 may include at least one of Ag, Al, Mg, Li, Ca, Cu, LiF/Ca, LiF/Al, MgAg, and CaAg, and may be formed in a form of a thin film having a thickness of several to several tens of nanometer.

The light-emitting elements may include a first light-emitting element, a second light-emitting element, and a third light-emitting element, which are spaced apart from each other. For example, the first light-emitting element may emit red light, the second light-emitting element may emit green light, and the third light-emitting element may emit blue light.

A pixel-defining film 115 may be formed between the common electrode 150 and the pixel electrodes 131, 132, and 133 of the respective pixels PX1, PX2, and PX3.

The pixel-defining film 115 may include first openings C11, C12, and C13 surrounding edges of the pixel electrodes 131, 132, and 133 and exposing their central portions in a plan view, respectively. In other words, the pixel-defining film 115 may cover edges of the pixel electrodes 131, 132, and 133, and may include the first openings C11, C12, and C13 that define light-emitting areas of the light-emitting elements, respectively. The first openings C11, C12, and C13 may have different diameters in a plan view.

The pixel-defining film 115 may include an organic material such as polyimide or HMDSO. In an embodiment, the pixel-defining film 115 may include a light-blocking material that surrounds outer edges of the pixel electrodes 131, 132, and 133 and have circular first openings C11, C12, and C13 in a plan view. The light-blocking material may include, for example, at least one of carbon black, carbon nanotubes (CNTs), and a black dye.

The thin-film encapsulation layer 160 covering the display area DA may be arranged on the common electrode 150. The thin-film encapsulation layer 160 may seal the light-emitting elements to suppress deterioration of the light-emitting elements due to moisture and oxygen contained in external air. As illustrated in FIG. 2, the thin-film encapsulation layer 160 may include a first inorganic layer 161, an organic layer 162, and a second inorganic layer 163.

The first inorganic layer 161 may include silicon oxide, silicon nitride, and/or silicon oxynitride.

The organic layer 162 may cover the first inorganic layer 161 that is not flat, and the upper surface of the organic layer 162 may be substantially flat. The organic layer 162 may include at least one of polyethylene terephthalate, polyethylene naphthalate, polycarbonate, polyimide, polyethylene sulfonate, polyoxymethylene, polyarylate, polyacrylate, and HMDSO.

The second inorganic layer 163 may cover the organic layer 162 and may include silicon oxide, silicon nitride, and/or silicon oxynitride.

As such, the thin-film encapsulation layer 160 may have a multilayer structure including the first inorganic layer 161, the organic layer 162, and the second inorganic layer 163, and thus, in case that a crack is formed in the thin-film encapsulation layer 160, the cracks may be prevented from being connected to each other between the first inorganic layer 161 and the organic layer 162 or between the organic layer 162 and the second inorganic layer 163. This may prevent or reduce the formation of a passage through which moisture or oxygen from the outside penetrates into the display area DA.

Although not illustrated in FIG. 2, a capping layer (not shown) that improves light efficiency and protects the light-emitting elements may be further provided between the common electrode 150 and the thin-film encapsulation layer 160.

The touch sensing layer 170 may be provided on the thin-film encapsulation layer 160. The touch sensing layer 170 may include a first insulating layer 171, a second insulating layer 172 formed on the first insulating layer 171, and multiple touch electrodes 173 formed between the first insulating layer 171 and the second insulating layer 172. The touch electrodes 173 are not limited to the structure illustrated in FIG. 2, and may have various electrode structures such as a mesh electrode pattern or a transparent segment electrode.

The touch sensing layer 170 may sense a touch input based on a change in mutual capacitance caused by the touch input. For example, in case that a touch input is applied, the mutual capacitance may change due to the touch input, and a touch sensing unit (not shown) connected to the touch sensing layer 170 may detect the position in which the mutual capacitance has changed, to sense the touch input. However, the disclosure is not limited to a specific touch sensing method.

The color conversion layer 200 may be arranged on the display layer 100. For example, the scattering layer 230 may be arranged on the touch sensing layer 170, the color filter layer 250 may be arranged on the scattering layer 230, and the second substrate 210 may be arranged on the color filter layer 250.

The color filter layer 250 may be arranged between the second substrate 210 and the scattering layer 230, and may be arranged in the light-emitting areas of the pixel PX1, PX2, and PX3. In other words, the color filter layer 250 may be arranged to correspond to the first openings C11, C12, and C13 that define the light-emitting areas of the light-emitting elements.

The color filter layer 250 may include color filters 251, 252, and 253 that filter light generated from the light-emitting elements, and transmit the filtered light to the outside. The color filters 251, 252, and 253 may include a first color filter 251 arranged above the first light-emitting element, a second color filter 252 arranged above the second light-emitting element, and a third color filter 253 arranged above the third light-emitting element.

The color filters 251, 252, and 253 may have a color corresponding to the light-emitting areas of the pixels, respectively. For example, in case that the first pixel PX1 emits red light, the first color filter 251 may transmit the red light, in case that the second pixel PX2 emits green light, the second color filter 252 may transmit the green light, and in case that the third pixel PX3 emits blue light, the third color filter 253 may transmit the blue light.

The first color filter 251, which is a red color filter, may include a red pigment or dye, the second color filter 252, which is a green color filter, may include a green pigment or dye, and the third color filter 253, which is a blue color filter, may include a blue pigment or dye. The red pigment, the green pigment, and the blue pigment may be a pigment commonly used for forming color filters. For example, a C.I. Pigment red-based pigment may be used as a red pigment, a C.I. Pigment green-based pigment may be used as a green pigment, and a phthalocyanine-based pigment or an indanthrone blue pigment may be used as a blue pigment.

By applying a color filter layer 250, instead of a polarizing layer, to the display apparatus 10, the light emission efficiency may be improved. However, in a display apparatus 10 to which only a color filter layer 250 is applied, the color filters 251, 252, and 253 may be regularly arranged to match the corresponding light-emitting elements, respectively, and thus, a diffraction interference reflection pattern may be formed due to a periodic grating.

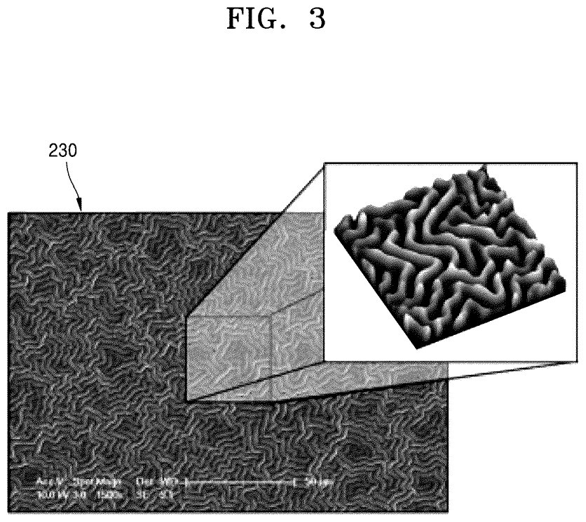

To improve visibility, the scattering layer 230 including irregular wrinkles may be arranged under the color filter layer 250. The scattering layer 230 including irregular wrinkles may scatter reflected light and thus weaken the diffraction pattern. The scattering layer 230 will be described in detail below with reference to FIG. 3.

The second substrate 210 may be arranged on the color filter layer 250. The second substrate 210 may include transparent glass, a plastic, or the like.

In an embodiment, the color conversion layer 200 may include a black matrix BM. The black matrix BM may be arranged between the scattering layer 230 and the second substrate 210, and between the color filters 251, 252, and 253.

The black matrix BM may be located above the pixel-defining film 115 and define an opening area through which light passes. In other words, the black matrix BM may include second openings C21, C22, and C23 corresponding to the first openings C11, C12, and C13, respectively.

The black matrix BM in the display area DA may have the circular second openings C21, C22, and C23 that open the light-emitting areas of the pixels PX1, PX2, and PX3, respectively. The second openings C21, C22, and C23 of the black matrix BM may overlap the first openings C11, C12, and C13 in a plan view formed in the pixel-defining film 115 of the pixels PX1, PX2, and PX3, respectively.

The black matrix BM in the peripheral area PA may surround the entire peripheral area PA without any opening. The black matrix BM surrounding the peripheral area PA may reduce reflection of external light from various wires arranged in the peripheral area PA.

The black matrix BM may include a material capable of blocking light. For example, the black matrix BM may include at least one of a metal such as chromium oxide (CrOₓ), an opaque organic film material, carbon black, carbon nanotubes, and a black dye. The black matrix BM may include a coloring agent such as a pigment or a dye. The black matrix BM may have a single-layer or multi-layer structure.

FIG. 2 schematically illustrates that the color filters 251, 252, and 253 cover portions of the black matrix BM, but the disclosure is not limited thereto, and depending on the order of forming the black matrix BM and the color filters 251, 252, and 253, the black matrix BM may cover portions of the color filters 251, 252, and 253, or the color filters 251, 252, and 253 may cover portions of the black matrix BM.

In an embodiment, the color conversion layer 200 may have an effect of the black matrix BM through a combination of the first color filter 251, the second color filter 252, and the third color filter 253, to replace the black matrix BM.

FIG. 3 is a plan view schematically illustrating a portion of a scattering layer, according to an embodiment of the disclosure.

The display apparatus 10 to which the color filters 251, 252, and 253 are applied may have artifacts caused by a diffraction grating. Even in case that a scattering layer including a scatterer is introduced to solve this issue, an issue of luminance being reduced due to light scattered by the scatterer may occur.

The scattering layer 230 according to an embodiment of the disclosure for solving the above issue may include irregular wrinkles. The wrinkles may be arranged on the scattering layer 230 in a direction perpendicular to light of the display apparatus 10 is emitted. Light generated from below the scattering layer 230 may be randomly refracted by the wrinkles of the scattering layer 230, such that the optical path may be randomly changed, and thus, the diffraction grating artifact issue may be solved.

The scattering layer 230 including irregular wrinkles may alleviate the issue of reflection diffraction artifacts compared to a scattering layer including a scatterer, and may improve the light efficiency of the display apparatus 10 by alleviating or eliminating back scattering.

Assuming that the light emission efficiency of a display apparatus to which only a polarizing layer is applied is 100%, the light emission efficiency of a display apparatus to which color filters are applied may be 150%, the light emission efficiency of a display apparatus in which a scattering layer including a scatterer is applied to color filters may be 125%, and the light emission efficiency of the display apparatus 10 in which a scattering layer including irregular wrinkles is applied to color filters may be 145%.

The light emission efficiency of the display apparatus 10 in which the scattering layer 230 including irregular wrinkles is applied to the color filters 251, 252, and 253 may be about 5% lower than the light emission efficiency of a display apparatus to which only a color filter is applied, however, unlike the display apparatus to which only a color filter is applied, the display apparatus 10 in which the scattering layer 230 including irregular wrinkles is applied to the color filters 251, 252, and 253 may not produce diffraction grating artifacts, resulting in improved display quality and visibility.

For example, the scattering layer 230 including irregular wrinkles may have a thickness in a range of about 0.5 μm to about 10 μm, a refractive index in a range of about 1.45 to about 1.75, and a step difference between valleys and ridges in a range of about 0.1 μm to about 8 μm.

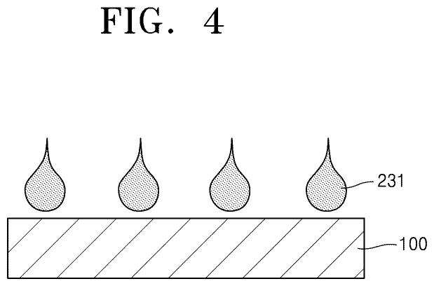

The scattering layer 230 may include a photocrosslinking reaction material 231 (see FIG. 4). For example, the photocrosslinking reaction material 231 (see FIG. 4) may include at least one of materials represented by Formulae 1 to 15 below.

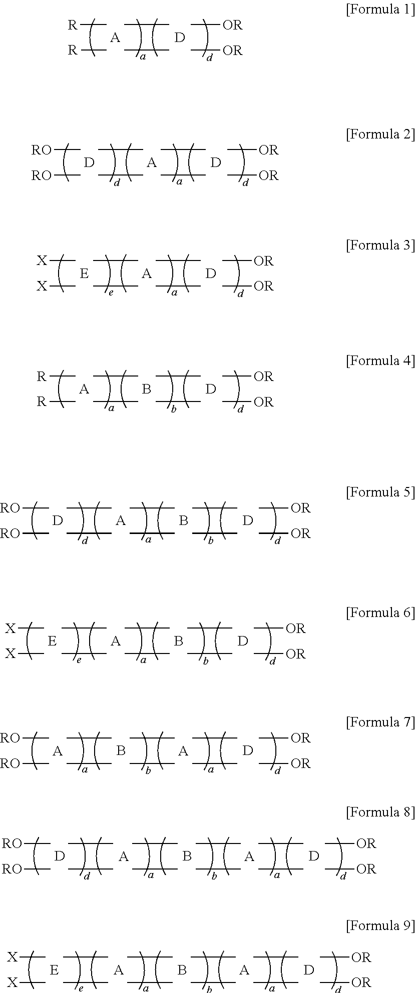

In Formulae 1 to 9 above,

A may be

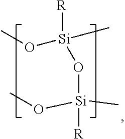

B may be

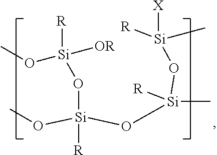

D may be

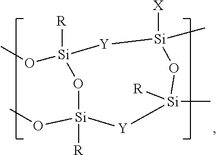

E may be and

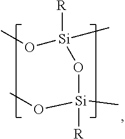

In Formulae 1 to 9 and in B, X may be a halogen atom.

In D, Y may be (SiO₃/2R)4+2nO, and

In Formulae 1 to 9, a, b, c, and d may each independently be 1 to 100.

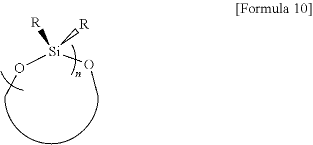

In Formula 10, n may be 1 to 20.

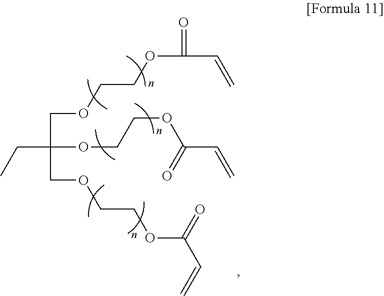

In Formula 11, n may be 1 to 5.

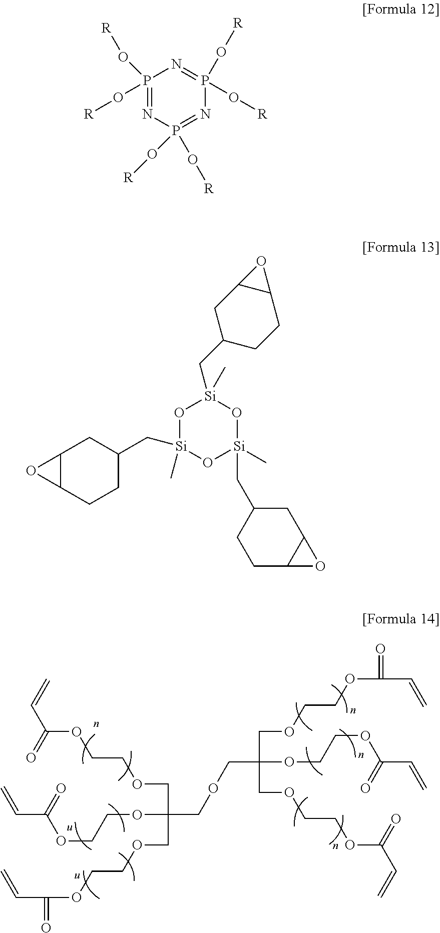

In Formula 14, n may be 1 to 5.

In Formulae 1 to 14,

R may be

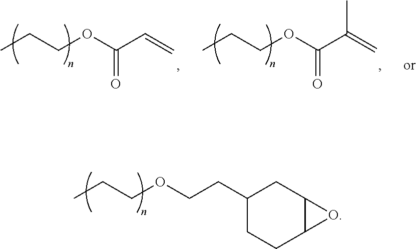

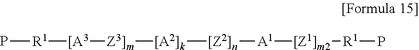

In Formula 15 above,

n may be 0 or 1, m may be 0 to 6, m2 may be 0 to 6, k may be 0 or 1, P may be a polymerizable group,

R¹ may be selected from the group consisting of H, halogen, substituted or unsubstituted C₁₋₂₅ alkyl, substituted or unsubstituted C₂₋₂₅ alkenyl, substituted or unsubstituted C₂₋₂₅ alkynyl, and substituted or unsubstituted C₃₋₂₅ cycloalkyl.

In case that C₁₋₂₅ alkyl, C₂₋₂₅ alkenyl, C₂₋₂₅ alkynyl, or C₃₋₂₅ cycloalkyl is substituted, each carbon atom may be independently substituted with —O—, —S—, —CO—, —CO—O—, —O—CO—, or —OC(O)—O—, or each hydrogen atom may be independently substituted with C₁₋₁₂ alkyl, C₂₋₁₂ alkenyl, or C₂₋₁₂ alkynyl.

A¹, A², and A³ may each independently be an aryl group, a heteroaryl group, an alicyclic group, or a heterocyclic group, or A¹, A², and A³ may each independently be a fused ring including an aryl group, a heteroaryl group, an alicyclic group, or a heterocyclic group.

A¹, A², and A³ may each be independently substituted with —Z¹—Sₚ—Z¹—P or L,
L may be H, F, Cl, Br, I, —CN, —NO, —NCO, —NCS, —OCN, —SCN, —C(═O)N(R⁰)₂, —C(═O)R⁰, an allyl-substituted silyl group, a C₃₋₂₀ cycloalkyl group, an alkoxy group, an alkylcarbonyl group, an alkoxycarbonyl group, or a C₁₋₂₅ alkylcarbonyloxy group, P may be a polymerizable group, Sₚ may be a spacer group or bond,
Z¹ may be —O—, —S—, —CO—, —CO—O—, —OCO—, —O—CO—O—, —OCH₂—, —SCH₂—, —CH₂S—, —CF₂O—, —OCF₂—, —CF₂S—, —SCF₂—, —(CH₂)ₙ₁—, —CF₂CH₂—, —CH₂CF₂—, —(CF₂)ₙ₁, —CH═CH—, CF═CF—, —C≡C—, —CH═CH—COO—, —OCO—CH═CH—, —(CR⁰,R⁰⁰)ₙ₁—, —CH(—Sₚ—P)—, —CH₂CH—(—Sₚ—P)—, —(CH(—Sₚ—P)CH(—Sₚ—P)—, or —O—(CH₂)—OCO—(CH₂)ₙ,
Z² may be —O—, —S—, —CO—, —CO—O—, —OCO—, —O—CO—O—, —OCH₂—, —SCH₂—, —CH₂S—, —CF₂O—, —OCF₂—, —CF₂S—, —SCF₂—, —(CH₂)ₙ₁—, —CF₂CH₂—, —CH₂CF₂—, —(CF₂)ₙ₁, —CH═CH—, CF═CF—, —C≡C—, —CH═CH—COO—, —OCO—CH═CH—, —(CR⁰,R⁰⁰)ₙ₁—, —CH(—Sₚ—P)—, —CH₂CH—(—Sₚ—P)—, or —(CH(—Sₚ—P)CH(—Sₚ—P)—,
Z³ may be —O—, —S—, —CO—, —CO—O—, —OCO—, —O—CO—O—, —OCH₂—, —SCH₂—, —CH₂S—, —CF₂O—, —OCF₂—, —CF₂S—, —SCF₂—, —(CH₂)ₙ₁—, —CF₂CH₂—, —CH₂CF₂—, —(CF₂)ₙ₁, —CH═CH—, CF═CF—, —C≡C—, —CH═CH—COO—, —OCO—CH═CH—, —(CR⁰,R⁰⁰)ₙ₁—, —CH(—Sₚ—P)—, —CH₂CH—(—Sₚ—P)—, or —(CH(—Sₚ—P)CH(—Sₚ—P)—,
in Z¹, Z², and Z³, n1 may be 1 to 4, R⁰ may be a C₁₋₁₂ alkyl group, R⁰⁰ may be H or a C₁₋₁₂ alkyl group, and Sₚ may be a spacer group or bond.

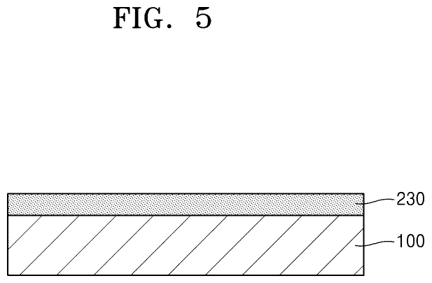

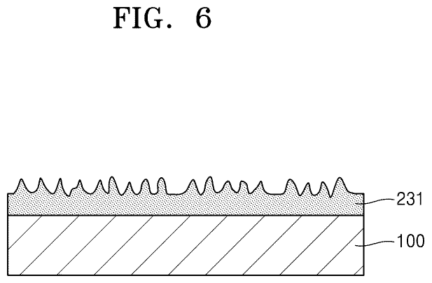

FIGS. 4 to 6 are schematic cross-sectional views illustrating a process of manufacturing a scattering layer, according to an embodiment of the disclosure.

A method of manufacturing the display apparatus 10 according to an embodiment of the disclosure may include producing the display layer 100, forming the scattering layer 230 on the display layer 100, and forming the color filter layer 250 on the scattering layer 230.

The producing of the display layer 100 may include sequentially forming the substrate 110, light-emitting elements on the substrate 110, the thin-film encapsulation layer 160 on the light-emitting elements, and the touch sensing layer 170 on the thin-film encapsulation layer 160.

The light-emitting elements may include the pixel electrodes 131, 132, and 133, the common electrode 150 located on the pixel electrodes 131, 132, and 133, and the emission layers 141, 142, and 143 arranged between the common electrode 150 and the pixel electrodes 131, 132, and 133.

The light-emitting elements may include a first light-emitting element that emits red light, a second light-emitting element that emits green light, and a third light-emitting element that emits blue light, which are spaced apart from each other.

The display layer 100 may further include the pixel-defining film 115 that covers edges of the pixel electrodes 131, 132, and 133, and includes the first openings C11, C12, and C13 that define light-emitting areas of the light-emitting elements.

Referring to FIGS. 4 to 6, the forming of the scattering layer 230 may include applying, on the display layer 100, a photocrosslinking reaction material 231 for forming the scattering layer 230, and curing the applied photocrosslinking reaction material 231.

For example, first, a photocrosslinking reaction material 231 may be applied to the front surface of the touch sensing layer 170 or selectively applied only to a specific area of the touch sensing layer 170, by using an inkjet or a slit coater.

The applied photocrosslinking reaction material 231 may be cured by ultraviolet (UV) or heat treatment. As a UV curing method, the applied photocrosslinking reaction material 231 may be cured by irradiating the front surface or part of the applied photocrosslinking reaction material 231 with UV light (e.g., about 365 nm or about 395 nm) at about 0.5 to about 3 J/cm².

As a curing method using heat treatment, the applied photocrosslinking reaction material 231 may be heat-cured at about 80° C. to about 100° C.

In both of the above curing methods, wrinkles may be formed on the surface of the photocrosslinking reaction material 231 as the surface and a central portion of the applied photocrosslinking reaction material 231 differ from each other in curing rate.

In the scattering layer 230 formed through the above steps, irregular wrinkles may be formed due to the curing of the photocrosslinking reaction material 231. The wrinkles of the scattering layer 230 may be formed on the upper surface of the scattering layer 230, for example, on the surface in the direction in which light of the display apparatus 10 is emitted from the scattering layer 230.

The forming of the color filter layer 250 may include forming the color filters 251, 252, and 253 on the scattering layer 230 to correspond to the first openings C11, C12, and C13, respectively.

The color filter layer 250 may include the first color filter 251 arranged above the first light-emitting element, the second color filter 252 arranged above the second light-emitting element, and the third color filter 253 arranged above the third light-emitting element.

In an embodiment, the forming of the color filter layer 250 may further include forming the black matrix BM. The color filter layer 250 may be formed first on the scattering layer 230 and the black matrix BM may be formed, or the black matrix BM may be formed first on the scattering layer 230 and the color filter layer 250 may be formed.

The black matrix BM may be formed on the scattering layer 230 and may form the second openings C21, C22, and C23 corresponding to the first openings C11, C12, and C13, respectively.

Regardless of the order of forming the black matrix BM and the color filter layer 250, the color filters 251, 252, and 253 may be formed to be arranged between portions of the black matrix BM. In other words, the color filters 251, 252, and 253 may be arranged in the second openings C21, C22, and C23, respectively.

After forming the color filter layer 250, the second substrate 210 may be formed on the color filter layer 250.

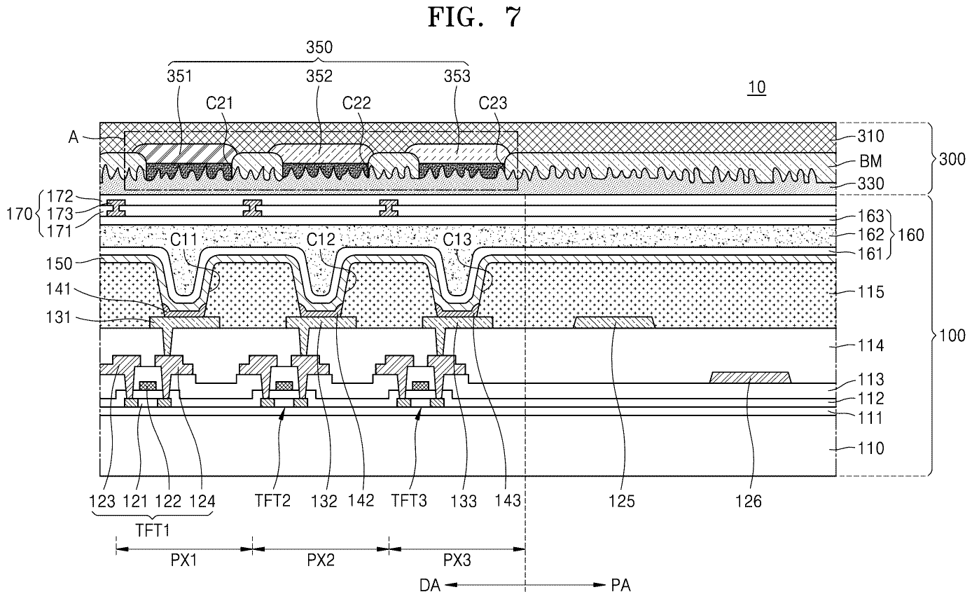

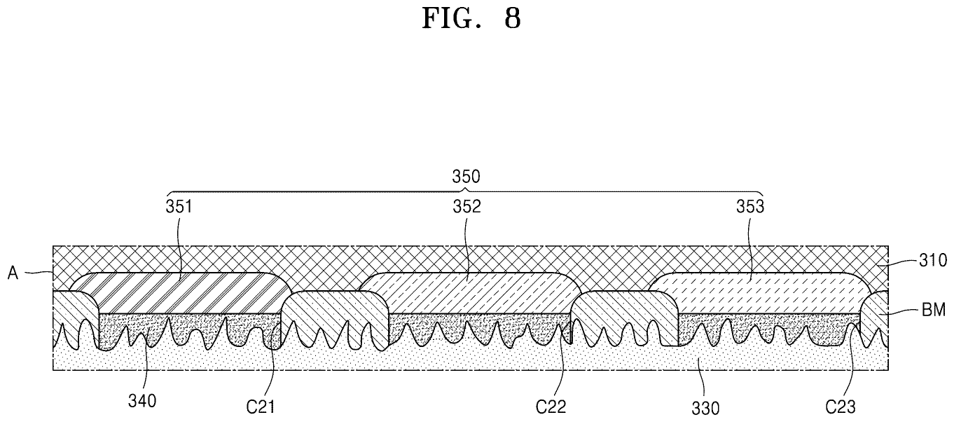

FIG. 7 is a schematic cross-sectional view schematically illustrating another embodiment of portion I of the display apparatus illustrated in FIG. 1, and FIG. 8 is an enlarged view of area A illustrated in FIG. 7.

In an embodiment, the display apparatus 10 may include a color conversion layer 300 on the display layer 100. The color conversion layer 300 may include a color filter layer 350 on a scattering layer 330 including irregular wrinkles, and planarization layers 340 may be further arranged between the scattering layer 330 and the color filter layer 350.

For example, the planarization layers 340 may be formed under color filters 351, 352, and 353 to correspond to the first openings C11, C12, and C13, respectively. In case that the color conversion layer 300 includes the black matrix BM, the planarization layers 340 may be arranged between the scattering layer 330 and the color filters 351, 352, and 353 in the second opening C21, C22, and C23 of the black matrix BM, respectively.

The planarization layers 340 may be arranged on the wrinkles of the scattering layer 330 to flatten an upper portion of the scattering layer 330 such that the color filter layer 350 may be stably stacked. The planarization layer 340 may cover at least ridges of the wrinkles of the scattering layer 330.

The planarization layers 340 may be arranged on the scattering layer 330 to have a refractive index matching with the scattering layer 330 and to have compatibility with the color filter layer 350. The planarization layer 340 may have a lens-like effect by creating a difference in refractive index.

The refractive indices of the planarization layers 340 may be less than the refractive index of the scattering layer 330. In case that the difference in refractive index between the planarization layers 340 and the scattering layer 330 is 0.1 to 0.2, the light extraction rate of the display apparatus 10 may be improved. For example, the refractive index of the scattering layer 330 may be in a range of about 1.45 to about 1.75, and the refractive indices of the planarization layers 340 may be in a range of about 1.20 to about 1.44.

Forming the planarization layer 340 may be performed between the forming of the scattering layer 330 and the forming of the color filter layer 350.

For example, after the scattering layer 330 is formed, the planarization layer 340 may be formed, and the color filter layer 350 may be formed. In case that the black matrix BM is formed, the black matrix BM may be formed after the formation of the scattering layer 330 and before the formation of the planarization layer 340, or may be formed after the formation of the planarization layer 340 and the color filter layer 350.

The description of the color conversion layer 200 provided above with reference to FIGS. 2 to 6 may be applied to the color conversion layer 300, as long as it does not conflict with the above description.

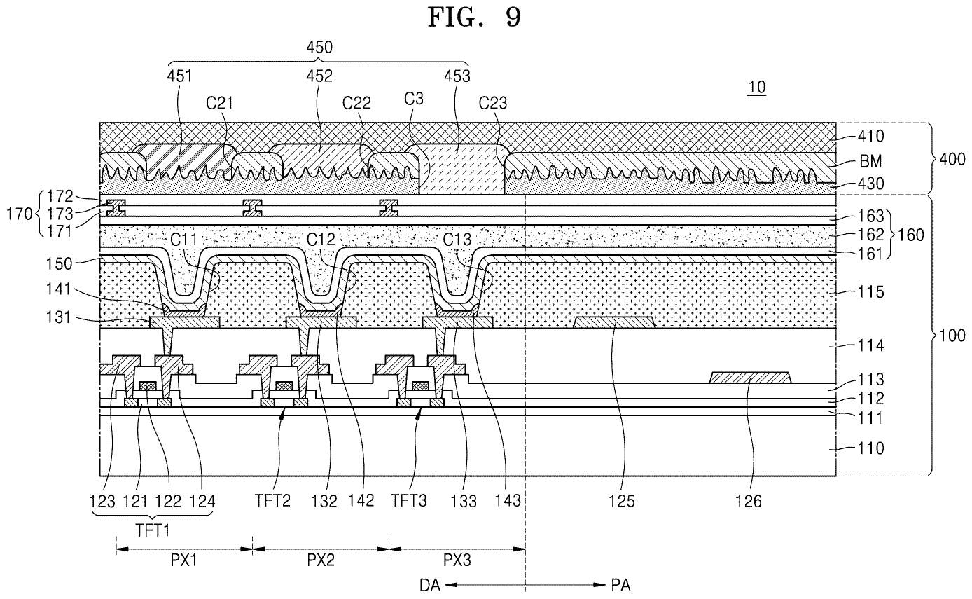

FIG. 9 is a schematic cross-sectional view schematically illustrating another embodiment of portion I of the display apparatus illustrated in FIG. 1.

In an embodiment, the display apparatus 10 may include a color conversion layer 400 on the display layer 100. The color conversion layer 400 may include a color filter layer 450 on a scattering layer 430 including irregular wrinkles.

The color filter layer 450 may include color filters 451, 452, and 453 that filter light generated from the light-emitting elements, and transmit the filtered light to the outside. The color filters 451, 452, and 453 may include a first color filter 451 arranged above the first light-emitting element, a second color filter 452 arranged above the second light-emitting element, and a third color filter 453 arranged above the third light-emitting element.

The color filters 451, 452, and 453 may include a color corresponding to the light-emitting areas of the pixels, respectively. For example, in case that the first pixel PX1 emits red light, the first color filter 451 may transmit the red light, in case that the second pixel PX2 emits green light, the second color filter 452 may transmit the green light, and in case that the third pixel PX3 emits blue light, the third color filter 453 may transmit the blue light.

The first color filter 451, which is a red color filter, may include a red pigment or dye, the second color filter 452, which is a green color filter, may include a green pigment or dye, and the third color filter 453, which is a blue color filter, may include a blue pigment or dye. The red pigment, the green pigment, and the blue pigment may be a pigment commonly used for forming color filters. For example, a C.I. Pigment red-based pigment may be used as a red pigment, a C.I. Pigment green-based pigment may be used as a green pigment, and a phthalocyanine-based pigment or an indanthrone blue pigment may be used as a blue pigment.

The scattering layer 430 may further include a third opening C3 formed by removing an area of the scattering layer 430 under the third color filter 453. In other words, the third opening C3 may be arranged under the second opening C23 to correspond to the second opening C23 in which the third color filter 453 is arranged. For example, the third opening C3 and the second opening C23 may have a same width. The third opening C3 may be formed corresponding to the first opening C13 formed by the pixel-defining film 115 of the third pixel PX3 and defining the light-emitting area of the light-emitting element.

The scattering layer 430 may be formed by, before forming the color filter layer 450, removing an area of the scattering layer 430 under the third color filter 453, for example, a portion of the scattering layer 430 corresponding to the first opening C13, to form the third opening C3.

The description of the color conversion layer 200 provided above with reference to FIGS. 2 to 6 may be applied to the color conversion layer 400, as long as it does not conflict with the above description.

Each of the embodiments described above may be implemented independently, but the structure of each embodiment may be applied to other embodiments in combination.

The particular implementations shown and described herein are illustrative examples of the embodiments and are not intended to otherwise limit the scope of the embodiments in any way.

The term “the” and other demonstratives similar thereto in the descriptions of embodiments (especially in the following claims) should be understood to include a singular form and plural forms. Further, recitation of ranges of values herein are merely intended to serve as a shorthand method of referring individually to each separate value falling within the range, unless otherwise indicated herein, and each separate value is incorporated into the specification as if it were individually recited herein. Finally, operations of all methods described herein may be performed in any suitable order unless otherwise indicated herein or otherwise clearly contradicted by context. The embodiments are not limited to the described order of the operations. The use of any and all examples, or exemplary language in embodiments, is intended merely to better illuminate the embodiments and does not pose a limitation on the scope of the embodiments unless otherwise described. Also, numerous modifications and adaptations will be readily apparent to those skilled in the art without departing from the spirit and scope of the disclosure.

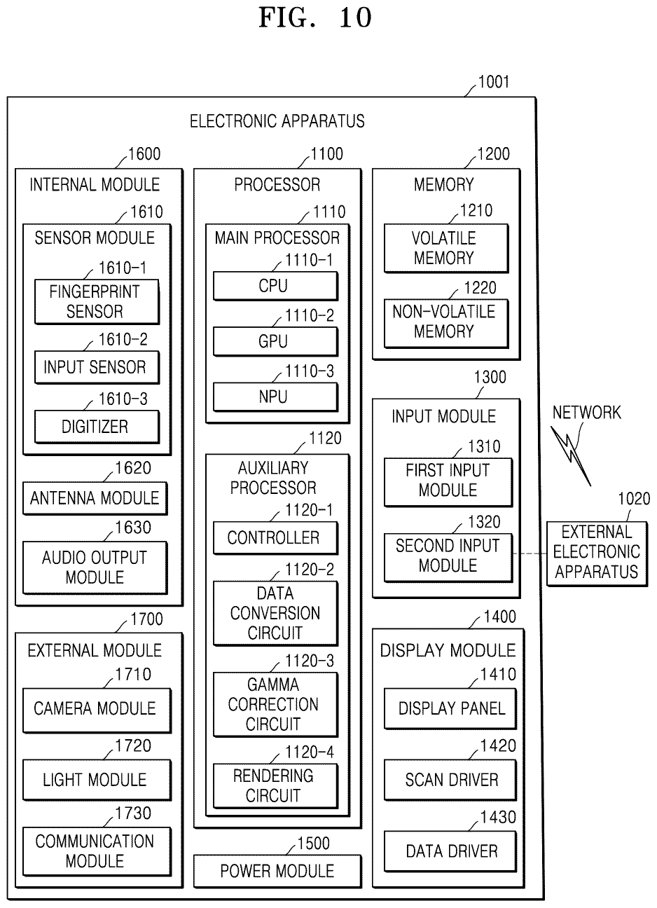

FIG. 10 is a schematic block diagram of an electronic apparatus according to embodiments of the disclosure.

An electronic apparatus 1001 may output various pieces of information through a display module 1400 in an operating system. The electronic apparatus 1001 may include the display apparatus 10, and the display apparatus 10 may include at least the display module 1400.

In case that a processor 1100 executes an application stored in a memory 1200, the display module 1400 may provide application information to a user through a display panel 1410.

The processor 1100 may obtain an external input through an input module 1300 or a sensor module 1610, and execute an application corresponding to the external input. For example, in case that a user selects a camera icon displayed on the display panel 1410, the processor 1100 may obtain a user input through an input sensor 1610-2 and activate a camera module 1710. The processor 1100 may deliver, to the display module 1400, image data corresponding to a captured image obtained through the camera module 1710. The display module 1400 may display an image corresponding to the captured image through the display panel 1410.

For example, in case that personal information authentication is performed in the display module 1400, a fingerprint sensor 1610-1 may obtain input fingerprint information as input data. The processor 1100 may compare the input data obtained through the fingerprint sensor 1610-1 with authentication data stored in the memory 1200, and execute an application according to a result of the comparison. The display module 1400 may display, through the display panel 1410, information obtained through execution according to logic of the application.

For example, in case that a music streaming icon displayed on the display module 1400 is selected, the processor 1100 may obtain a user input through the input sensor 1610-2 and activate a music streaming application stored in the memory 1200. In case that a music execution command is input in the music streaming application, the processor 1100 may activate an audio output module 1630 to provide the user with audio information corresponding to the music execution command.

The operation of the electronic apparatus 1001 has been briefly described above. Hereinafter, a configuration of the electronic apparatus 1001 will be described in detail. Some of the components of the electronic apparatus 1001 described below may be integrated into one component, and one component of the electronic apparatus 1001 may be separated into two or more components.

Referring to FIG. 10, the electronic apparatus 1001 may communicate with an external electronic apparatus 1002 via a network (e.g., a short-range wireless communication network or a long-range wireless communication network). According to an embodiment, the electronic apparatus 1001 may include the processor 1100 configured to operate by executing at least one program, the memory 1200 storing the at least one program, the input module 1300, the display module 1400, and a power module 1500 configured to supply power to the display module 1400.

According to an embodiment, the electronic apparatus 1001 may include an internal module 1600 and an external module 1700. The internal module 1600 may include the sensor module 1610 configured to detect an input and generate data corresponding to the input, an antenna module 1620 configured to transmit or receive data or power to or from an external electronic apparatus, and the audio output module 1630 configured to be controlled by the processor 1100 to output audio data. The external module 1700 may include the camera module 1710 configured to capture a still image and/or a moving image, a light module 1720 configured to output light, and a communication module 1730 configured to transmit or receive data between the electronic apparatus 1001 and the external electronic apparatus 1002.

According to an embodiment, at least one of the above-described components may be omitted from the electronic apparatus 1001, or one or more other components may be added to the electronic apparatus 1001. In an embodiment, some of the components described above (e.g., the sensor module 1610, the antenna module 1620, or the audio output module 1630) may be integrated into another component (e.g., the display module 1400).

The processor 1100 may execute software to control at least one other component (e.g., a hardware or software component) of the electronic apparatus 1001 connected to the processor 1100, and may perform various operations for data processing or computation. According to an embodiment, as at least a part of the data processing or computation, the processor 1100 may store a command or data received from another component (e.g., the input module 1300, the sensor module 1610, or a communication module 1730) in a volatile memory 1210, process the command or data stored in the volatile memory 1210, and store resulting data in a non-volatile memory 1220.

The processor 1100 may include a main processor 1110 and an auxiliary processor 1120. The main processor 1110 may include at least one of a central processing unit (CPU) 1110-1 and an application processor (AP). The main processor 1110 may further include at least one of a graphics processing unit (GPU) 1110-2, a communication processor (CP), and an image signal processor (ISP). The main processor 1110 may further include a neural processing unit (NPU) 1110-3. The NPU may be a processor specialized in processing an artificial intelligence model, and the artificial intelligence model may be generated through machine learning. The artificial intelligence model may include multiple neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination thereof, but the disclosure is not limited thereto. The artificial intelligence model may additionally or alternatively include a software structure in addition to the hardware structure. At least two of the processing units and processors described above may be implemented as a single integrated configuration (e.g., a single chip) or may be implemented as independent components (e.g., multiple chips).

The auxiliary processor 1120 may include a controller 1120-1. The controller 1120-1 may include an interface conversion circuit and a timing control circuit. The controller 1120-1 may receive an image signal from the main processor 1110, convert the data format of the image signal to fit the interface specifications with the display module 1400, and output image data. The controller 1120-1 may output various control signals for driving the display module 1400.

The auxiliary processor 1120 may further include a data conversion circuit 1120-2, a gamma correction circuit 1120-3, a rendering circuit 1120-4, etc. The data conversion circuit 1120-2 may receive image data from the controller 1120-1, and compensate the image data such that an image is displayed at a desired luminance according to the characteristics of the electronic apparatus 1001 or the user's settings, or convert the image data to reduce power consumption or compensate for an afterimage. The gamma correction circuit 1120-3 may convert image data or a gamma reference voltage, etc. such that an image displayed on the electronic apparatus 1001 has desired gamma characteristics. The rendering circuit 1120-4 may receive image data from the controller 1120-1 and render the image data by considering the pixel layout of the display panel 1410 applied to the electronic apparatus 1001. At least one of the data conversion circuit 1120-2, the gamma correction circuit 1120-3, and the rendering circuit 1120-4 may be integrated into another component (e.g., the main processor 1110 or the controller 1120-1). At least one of the data conversion circuit 1120-2, the gamma correction circuit 1120-3, and the rendering circuit 1120-4 may be integrated into a data driver 1430 described below.

The memory 1200 may store various pieces of data used by at least one component of the electronic apparatus 1001 (e.g., the processor 1100 or the sensor module 1610) and input data or output data regarding a command related thereto. The memory 1200 may include at least one of the volatile memory 1210 and the non-volatile memory 1220.

The input module 1300 may receive a command or data to be used for a component of the electronic apparatus 1001 (e.g., the processor 1100, the sensor module 1610, or the audio output module 1630) from the outside of the electronic apparatus 1001 (e.g., a user or the external electronic apparatus 1002).

The input module 1300 may include a first input module 1310 into which a command or data is input from the user, and a second input module 1320 into which a command or data is input from the external electronic apparatus 1002. The first input module 1310 may include a microphone, a mouse, a keyboard, a key (e.g., a button), or a pen (e.g., a passive pen or an active pen). The second input module 1320 may support a designated protocol capable of enabling a wired or wireless connection with the external electronic apparatus 1002. According to an embodiment, the second input module 1320 may include a High-Definition Multimedia Interface (HDMI) unit, a Universal Serial Bus (USB) interface, a Secure Digital (SD) card interface, or an audio interface. The second input module 1320 may include a connector for physically connecting to the external electronic apparatus 1002, for example, an HDMI connector, a USB connector, an SD card connector, or an audio connector (e.g., a headphone connector).

The display module 1400 may provide information visually to the user. The display module 1400 may include the display panel 1410, a scan driver 1420, and the data driver 1430. The display module 1400 may further include a window, a chassis, and a bracket to protect the display panel 1410.

The display panel 1410 may include a liquid-crystal display panel, an organic light-emitting display panel, or an inorganic light-emitting display panel, and the type of the display panel 1410 is not limited to a particular type. The display panel 1410 may be of a rigid type or a flexible type to be rollable or foldable. The display module 1400 may further include a support that supports the display panel 1410, a bracket, a heat dissipation member, and the like.

The scan driver 1420 may be mounted on the display panel 1410 as a driving chip. In an embodiment, the scan driver 1420 may be integrated into the display panel 1410. For example, the scan driver 1420 may include an amorphous silicon TFT gate (ASG) driver circuit, a low-temperature polycrystalline silicon (LTPS) TFT gate driver circuit, or an oxide semiconductor TFT gate (OSG) driver circuit integrated into the display panel 1410. The scan driver 1420 may receive a control signal from the controller 1120-1, and output a scan signal to the display panel 1410 in response to the control signal.

The display panel 1410 may further include a light emission driver. The light emission driver may output a light emission control signal to the display panel 1410 in response to a control signal received from the controller 1120-1. The light emission driver may be implemented separately from the scan driver 1420 or may be integrated into the scan driver 1420.

The data driver 1430 may receive a control signal from the controller 1120-1, convert image data into analog voltages (e.g., data voltages) in response to the control signal, and output the data voltages to the display panel 1410.

The data driver 1430 may be integrated into another component (e.g., the controller 1120-1). The functions of the interface conversion circuit and the timing control circuit of the controller 1120-1 described above may be integrated into the data driver 1430.

The display module 1400 may further include a light emission driver, a voltage generation circuit, etc. The voltage generation circuit may output various voltages for driving the display panel 1410.

The power module 1500 may supply power to the components of the electronic apparatus 1001. The power module 1500 may include a battery to be charged with a voltage. The battery may include a non-rechargeable primary battery, a rechargeable secondary battery, or a fuel cell. The power module 1500 may include a power management integrated circuit (PMIC). The PMIC may provide optimized power for each of the modules described above and described below. The power module 1500 may include a wireless power transmission/reception member electrically connected to the battery. The wireless power transmission/reception member may include multiple coil-shaped antenna radiators.

The electronic apparatus 1001 may further include the internal module 1600 and the external module 1700. The internal module 1600 may include the sensor module 1610, the antenna module 1620, and the audio output module 1630. The external module 1700 may include the camera module 1710, the light module 1720, and the communication module 1730.

The sensor module 1610 may detect an input by the user's body or an input by a pen included in the first input module 1310, and generate an electric signal or a data value corresponding to the input. The sensor module 1610 may include at least one of the fingerprint sensor 1610-1, the input sensor 1610-2, and a digitizer 1610-3.

The fingerprint sensor 1610-1 may generate a data value corresponding to a fingerprint of the user. The fingerprint sensor 1610-1 may include an optical or capacitive fingerprint sensor.

The input sensor 1610-2 may generate a data value corresponding to coordinate information about an input by the user's body or an input by a pen. The input sensor 1610-2 may generate a data value based on an amount of change in electrostatic capacitance caused by the input. The input sensor 1610-2 may detect an input by a passive pen, or transmit and receive data with an active pen.

The input sensor 1610-2 may also measure a bio signal such as blood pressure, moisture, or body fat. For example, in case that a user touching a sensor layer or a sensing panel with a part of the user's body has not moved for a certain period of time, the input sensor 1610-2 may detect a bio signal based on a change in an electric field caused by the part of the user's body, and output information by the user to the display module 1400.

The digitizer 1610-3 may generate a data value corresponding to coordinate information about an input by a pen. The digitizer 1610-3 may generate a data value based on an electromagnetic change caused by the input. The digitizer 1610-3 may detect an input by a passive pen, or transmit and receive data with an active pen.

At least one of the fingerprint sensor 1610-1, the input sensor 1610-2, and the digitizer 1610-3 may be implemented as a sensor layer formed on the display panel 1410 through a continuous process. The fingerprint sensor 1610-1, the input sensor 1610-2, and the digitizer 1610-3 may be arranged on the upper side of the display panel 1410, or one of the fingerprint sensor 1610-1, the input sensor 1610-2, and the digitizer 1610-3, for example, the digitizer 1610-3, may be arranged on the lower side of the display panel 1410.

At least two of the fingerprint sensor 1610-1, the input sensor 1610-2, and the digitizer 1610-3 may be formed to be integrated into one sensing panel through a same process. In case that at least two of the fingerprint sensor 1610-1, the input sensor 1610-2, and the digitizer 1610-3 are integrated into one sensing panel, the sensing panel may be arranged between the display panel 1410 and a window arranged on the upper side of the display panel 1410. According to an embodiment, the sensing panel may be arranged on the window, but the location of the sensing panel is not particularly limited.

At least one of the fingerprint sensor 1610-1, the input sensor 1610-2, and the digitizer 1610-3 may be embedded in the display panel 1410. For example, at least one of the fingerprint sensor 1610-1, the input sensor 1610-2, and the digitizer 1610-3 may be formed simultaneously through a process of forming elements (e.g., light-emitting elements or transistors) included in the display panel 1410.

The sensor module 1610 may generate an electrical signal or a data value corresponding to an internal state or an external state of the electronic apparatus 1001. The sensor module 1610 may further include, for example, a gesture sensor, a gyro sensor, a barometric sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1620 may include one or more antennas for transmitting or receiving signals or power to or from the outside. According to an embodiment, the communication module 1730 may transmit or receive a signal to or from an external electronic apparatus through an antenna suitable for a communication method. An antenna pattern of the antenna module 1620 may be integrated into one component of the display module 1400 (e.g., the display panel 1410), or the input sensor 1610-2.

The audio output module 1630 may be a device for outputting an audio signal to the outside of the electronic apparatus 1001, and may include, for example, a speaker used for general purposes such as multimedia reproduction or recording reproduction, and a receiver used exclusively for call reception. According to an embodiment, the receiver may be formed integrally with or separately from the speaker. An audio output pattern of the audio output module 1630 may be integrated into the display module 1400.

The camera module 1710 may capture a still image or a moving image. According to an embodiment, the camera module 1710 may include one or more lenses, image sensors, or image signal processors. The camera module 1710 may further include an IR camera capable of measuring the presence or absence of a user, the user's location, the user's gaze, etc.

The light module 1720 may provide light. The light module 1720 may include a light-emitting diode or a xenon lamp. The light module 1720 may operate in conjunction with the camera module 1710 or independently.

The communication module 1730 may support establishment of a wired or wireless communication channel between the electronic apparatus 1001 and the external electronic apparatus 1002, and execution of communication through the established communication channel. The communication module 1730 may include one of or both of a wireless communication module such as a cellular communication module, a short-range wireless communication module, or a global navigation satellite system (GNSS) communication module, and a wired communication module, such as a local area network (LAN) communication module, or a power line communication module. The communication module 1730 may communicate with the external electronic apparatus 1002 via a short-range communication network such as Bluetooth, Wi-Fi direct, or Infrared Data Association (IrDA), or via a long-range communication network such as a cellular network, the Internet, or a computer network (e.g., a LAN or a wide area network (WAN)). Various types of communication modules described above may be implemented as a single chip or as separate chips.

The input module 1300, the sensor module 1610, the camera module 1710, and the like may be used to control the operation of the display module 1400 in conjunction with the processor 1100.

The processor 1100 may output a command or data to the display module 1400, the audio output module 1630, the camera module 1710, or the light module 1720, based on input data received from the input module 1300. For example, the processor 1100 may generate image data in response to input data received through a mouse or an active pen, and output the image data to the display module 1400, or generate command data in response to the input data and output the image data to the camera module 1710 or the light module 1720. In case that no input data is received from the input module 1300 for a certain period of time, the processor 1100 may switch the operation mode of the electronic apparatus 1001 to a low-power mode or a sleep mode to reduce power consumption of the electronic apparatus 1001.

The processor 1100 may output a command or data to the display module 1400, the audio output module 1630, the camera module 1710, or the light module 1720, based on sensing data received from the sensor module 1610. For example, the processor 1100 may compare authentication data received from the fingerprint sensor 1610-1 with authentication data stored in the memory 1200, and execute an application based on a result of the comparison. The processor 1100 may execute a command or output corresponding image data to the display module 1400, based on sensing data detected by the input sensor 1610-2 or the digitizer 1610-3. In case that a temperature sensor is included in the sensor module 1610, the processor 1100 may receive temperature data regarding a measured temperature from the sensor module 1610, and perform brightness correction or the like on the image data based on the temperature data.

The processor 1100 may receive, from the camera module 1710, measurement data regarding the presence or absence of a user, the user's location, the user's gaze, etc. The processor 1100 may further perform luminance correction or the like on the image data based on the measurement data. For example, the processor 1100 that has determined the presence or absence of the user through an input from the camera module 1710 may output image data of which the luminance has been corrected through the data conversion circuit 1120-2 or the gamma correction circuit 1120-3, to the display module 1400.

Some of the components described above may be connected to each other by using a communication method between peripheral devices, for example, a bus, a general-purpose input/output (GPIO), a serial peripheral interface (SPI), a mobile industry processor interface (MIPI), or an ultra path interconnect (UPI) link, to exchange signals (e.g., commands or data) with each other. The processor 1100 may communicate with the display module 1400 through an interface that is pre-agreed therebetween, and for example, may use any of the above-described communication methods, but the disclosure is not limited to the above-described communication methods.

The electronic apparatus 1001 according to various embodiments disclosed herein may include various types of devices. The electronic apparatus 1001 may include, for example, at least one of a portable communication device (e.g., a smart phone), a computer device, a portable multimedia device, a portable medical device, a camera, a wearable device, and a home appliance. The electronic apparatus 1001 according to an embodiment of the disclosure is not limited to the above devices.

According to an embodiment of the disclosure, a display apparatus, a method of manufacturing the display apparatus, and an electronic apparatus may be implemented, in which a scattering layer is arranged between a color filter and light-emitting elements to reduce reflection diffraction artifacts, improve display quality, alleviate or eliminate back scattering, and thus improve light efficiency.

It should be understood that embodiments described herein should be considered in a descriptive sense only and not for purposes of limitation. Descriptions of features or aspects of each embodiment should typically be considered as available for other similar features or aspects in other embodiments.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a thin-film transistor on a substrate;
a light-emitting element electrically connected to the thin-film transistor;
a thin-film encapsulation layer on the light-emitting element;
a scattering layer on the thin-film encapsulation layer; and
a color filter layer on the scattering layer,
wherein the scattering layer has irregular wrinkles.

2. The display apparatus of claim 1, wherein the irregular wrinkles are arranged on the scattering layer in a direction perpendicular to a light of the display apparatus is emitted.

3. The display apparatus of claim 1, wherein a thickness of the scattering layer is in a range of about 0.5 μm to about 10 μm.

4. The display apparatus of claim 1, wherein a refractive index of the scattering layer is in a range of about 1.45 to about 1.75.

5. The display apparatus of claim 1, wherein a step difference between valleys and ridges of the scattering layer is in a range of about 0.1 μm to about 8 μm.

6. The display apparatus of claim 1, wherein the scattering layer comprises a photocrosslinking reaction material.

7. The display apparatus of claim 1, wherein
the light-emitting element comprises a pixel electrode, a common electrode located on the pixel electrode, and an emission layer arranged between the pixel electrode and the common electrode,
the display apparatus further comprises a pixel-defining film that covers an edge of the pixel electrode and includes a first opening that defines a light-emitting area of the light-emitting element, and
the color filter layer is arranged to correspond to the first opening.

8. The display apparatus of claim 7, further comprising:
a black matrix located on the pixel-defining film and including a second opening corresponding to the first opening.

9. The display apparatus of claim 8, wherein the black matrix comprises at least one of a metal, an opaque organic film material, carbon black, carbon nanotubes, and a black dye.

10. The display apparatus of claim 1, wherein
the light-emitting element comprises a first light-emitting element, a second light-emitting element, and a third light-emitting element, which are spaced apart from each other,
the first light-emitting element emits red light,
the second light-emitting element emits green light, and
the third light-emitting element emits blue light.

11. The display apparatus of claim 10, wherein the color filter layer comprises a first color filter arranged above the first light-emitting element, a second color filter arranged above the second light-emitting element, and a third color filter arranged above the third light-emitting element.

12. The display apparatus of claim 11, further comprising:
a third opening defined by removing an area of the scattering layer under the third color filter.

13. The display apparatus of claim 1, further comprising:
a planarization layer arranged between the scattering layer and the color filter layer.

14. A method of manufacturing a display apparatus, the method comprising:
producing a display layer;
forming a scattering layer on the display layer; and
forming a color filter layer on the scattering layer, wherein
the forming of the scattering layer comprises applying, on the display layer, a scattering layer forming material comprising a photocrosslinking reaction material, and curing the scattering layer forming material applied on the display layer, and
the scattering layer has irregular wrinkles formed on a surface of the scattering layer by the curing of the scattering layer forming material.

15. The method of claim 14, wherein the irregular wrinkles are formed on an upper surface of the scattering layer.

16. The method of claim 14, wherein the producing of the display layer comprises forming a substrate, a light-emitting element on the substrate, and a thin-film encapsulation layer on the light-emitting element.

17. The method of claim 16, wherein
the light-emitting element comprises a pixel electrode, a common electrode located on the pixel electrode, and an emission layer arranged between the pixel electrode and the common electrode,
the method further comprises forming a pixel-defining film covering an edge of the pixel electrode and including a first opening that defines a light-emitting area of the light-emitting element, and
the color filter layer is arranged to correspond to the first opening.

18. The method of claim 17, wherein
the light-emitting element comprises a first light-emitting element that emits red light, a second light-emitting element that emits green light, and a third light-emitting element that emits blue light, which are spaced apart from each other,
the color filter layer comprises a first color filter arranged above the first light-emitting element, a second color filter arranged above the second light-emitting element, and a third color filter arranged above the third light-emitting element, and
the method further comprises, before the forming of the color filter layer, forming a third opening by removing an area of the scattering layer under the third color filter.

19. The method of claim 14, further comprising:
between the forming of the scattering layer and the forming of the color filter layer, forming a planarization layer on the scattering layer.

20. An electronic apparatus comprising:
an input module;
a memory storing at least one program;
a processor that operates by executing the at least one program;
a display apparatus; and
a power module that supplies power to the display apparatus, wherein
the processor controls the input module to obtain data, and controls the display apparatus to visually display the data,
the display apparatus comprises:
a thin-film transistor on a substrate;
a light-emitting element electrically connected to the thin-film transistor;
a thin-film encapsulation layer on the light-emitting element;
a scattering layer on the thin-film encapsulation layer; and
a color filter layer on the scattering layer, and
the scattering layer has irregular wrinkles.
